(19) United States
(12) Patent Application Publication
(10) Pub. No.: US 2015/0183188 A1
(43) Pub. Date: Jul. 2, 2015

(54) GROUP IV NANOWIRE STRUCTURES, METHODS AND APPLICATIONS

(71) Applicant: CORNELL UNIVERSITY, Ithaca, NY (US)

(72) Inventors: Benjamin Richards, Ithaca, NY (US); Tobias Hanrath, Ithaca, NY (US)

(73) Assignee: CORNELL UNIVERSITY, Ithaca, NY (US)

(21) Appl. No.: 14/408,655

(22) PCT Filed: Jun. 24, 2013
(86) PCT No.: PCT/US13/47263

§ 371 Date: Dec. 17, 2014

Related U.S. Application Data
(60) Provisional application No. 61/663,002, filed on Jun. 22, 2012.

(51) Int. Cl. B32B 15/01

(52) U.S. Cl. CPC B32B 15/013; B32B 15/01

(57) ABSTRACT

Methods for fabricating a nanowire composite, and a resulting article that includes the nanowire composite, are all adaptable to roll-to-roll processing by using a flexible substrate including a group IV nanowire growth surface, and locating and forming a group IV nanowire material layer upon the group IV nanowire growth surface. Under particular conditions of processing, group IV nanowire material layer nanowires may be located and formed perpendicular to a plane of the flexible substrate. Exemplary roll-to-roll processing apparatus are also considered.

### CROSS-REFERENCE TO RELATED APPLICATION

This application is related to, and derives priority from, U.S. Provisional Patent Application Ser. No. 61/663,002, filed 22 Jun. 2012 and titled Nanowire Structures, Methods and Applications, the contents of which are incorporated herein fully by reference.

### STATEMENT OF GOVERNMENT INTEREST

None.

### BACKGROUND

1. Field of the Invention

Embodiments relate generally to nanowire composite structures, related methods and related applications. More particularly, embodiments relate to improvements in nanowire composite structures, related methods and related applications.

2. Description of the Related Art

Nanowires have the potential to be the building blocks for a broad range of nanotechnologies. The unique physical, optical and electrical characteristics that arise from the one-dimensional structure of nanowires can be readily applied to a broad spectrum of nanotechnology applications.

Of particular interest within the context of nanotechnology applications of nanowires are nanowire structures, and methods for fabricating nanowire structures, that are commercially economical and efficient.

Since nanowire applications are likely to continue to grow in number and sophistication, desirable are nanowire structures, and methods for fabricating nanowire structures, that are commercially economical and efficient.

### SUMMARY

Embodiments include an article comprising a nanostructure comprising a nanowire composite, and related methods for fabricating the nanostructure comprising the nanowire composite. Embodiments also include an apparatus with which may be practiced the methods.

The article in accordance with the embodiments includes a flexible substrate that comprises a group IV nanowire growth surface, and that may be rolled into a coil. The group IV nanowire growth surface has located and formed thereupon a group IV nanowire material layer. Given that the flexible substrate may be rolled into a coil, the embodiments implicitly or inherently, if not explicitly, contemplate a related method for fabricating the nanowire composite that is a roll-to-roll method.

Another method for fabricating the nanowire composite in accordance with the embodiments provides for positioning a flexible substrate comprising a group IV nanowire growth surface within a reactor chamber. The method also provides for forming directly upon the group IV nanowire growth surface, while using a group IV precursor material, a group IV nanowire material layer.

Within the context of the foregoing methods in accordance with the embodiments, an apparatus in accordance with the embodiments includes a reactor chamber adapted for roll-to-roll processing. This particular apparatus also includes a group IV precursor source material source connected to the reactor chamber.

By “forming directly” the embodiments intend “forming in-situ” where the group IV precursor material reacts directly with the group IV nanowire growth surface.

The embodiments also provide for a combination of the roll-to-roll method in accordance with the embodiments and the in-situ group IV nanowire material layer fabrication in accordance with the embodiments.

A particular article in accordance with the embodiments includes a flexible substrate that may be rolled into a coil, the flexible substrate comprising a group IV nanowire growth surface. This particular article also includes a group IV nanowire material layer located upon the group IV nanowire growth surface.

A particular method for fabricating a nanostructure in accordance with the embodiments includes positioning within a reactor chamber a substrate comprising a group IV nanowire growth surface. This particular method also includes forming directly upon the group IV nanowire growth surface, while using a group IV precursor material, a group IV nanowire material layer.

Another particular method for fabricating a nanostructure in accordance with the embodiments includes positioning within a reactor chamber a flexible substrate that may be rolled into a coil, the flexible substrate comprising a group IV nanowire growth surface. This particular method also includes forming upon the group IV nanowire growth surface, while using a group IV nanowire precursor material, a group IV nanowire material layer.

A particular apparatus in accordance with the embodiments includes a reactor chamber adapted for roll-to-roll processing. The particular apparatus also includes a group IV precursor source material supply connected to the reactor chamber.

### BRIEF DESCRIPTION OF THE DRAWINGS

The objects, features and advantages of the embodiments are understood within the context of the Detailed Description of the Embodiments, as set forth below. The Detailed Description of the Embodiments is understood within the context of the accompanying drawings, that form a material part of this disclosure, wherein:

FIG. 1 illustrates in general end-use applications for a nanowire composite in accordance with the embodiments. Nanowires constitute essential building blocks for a broad range of emerging nanotechnologies.

FIG. 2a shows a piece of metal foil before and after a germanium nanowire formation thereupon to provide a nanowire composite in accordance with the embodiments. This is provided as a proof of concept. FIG. 2b shows a schematic diagram of a nanowire composite in accordance with the embodiments. This schematic diagram illustrates the nanowire material layer to metal substrate attachment without binder or additional catalyst for nanowire growth.

FIG. 3 shows a scanning electron micrograph of a nanowire composite in accordance with the embodiments including within a nanowire material layer both silicon nanowires and germanium nanowires.

FIG. 4 shows an x-ray diffraction pattern of crystalline germanium nanowire growth upon a copper substrate in accordance with the embodiments. This is an x-ray diffraction sweep of a germanium nanowires sample that was grown upon 100 nm layer of evaporated copper located and formed upon a silicon wafer. The copper was attached to the silicon wafer with a 5 nm chromium layer. The circles indicate x-ray diffraction from the substrate. The major peaks are 111, 011 and 311, left to right.

FIG. 5 shows a block flow diagram of a nanowire composite fabrication method in accordance with the embodiments. The block flow diagram shows possible different bulk metal materials, possibility of surface treatment, nanowire reaction, and the possibility of passivating the surface of the resulting nanowire composite or adding a functional group to the resulting nanowire composite. This figure illustrates the nanowire reactor as an integral part in the nanowire-device fabrication process. Key strength of the reactor design is the versatility to be integrated with a range of up-stream and down-stream processing components to enable fabrication of the broad range of technologies summarized in FIG. 1.

FIG. 6a shows a representative schematic diagram of a continuous roll-to-roll reactor for fabrication of a nanowire composite in accordance with the embodiments. (1) Feeding roll containing the flexible metal substrate located and formed coiled in part upon a core, (2) continuous nanowire growth onto the flexible substrate, (3) receiving roll with nanowires on flexible substrate. (4) container for the reaction environment which can be carried out at sub-atmospheric, atmospheric or super-atmospheric conditions. FIG. 6b shows a representative schematic diagram of a supercritical fluid reactor for a supercritical fluid fabrication of a nanowire composite in accordance with the embodiments. In this configuration the entire roll-to-roll process is contained in a vessel to maintain the required pressure environment. FIG. 6c shows a representative schematic diagram of an integrated reactor where a metal substrate rolls through a surface treatment or evaporation/sputtering unit, followed by the nanowire deposition reactor, followed by a surface passivating or functional group treatment unit. This reactor configuration enables continuous nanowire growth.

FIG. 7 shows the results of an electrochemical characterization of a germanium nanowire composite in accordance with the embodiments as an anode in a lithium ion battery, in comparison with a conventional lithium ion battery anode that was fabricated using unattached germanium nanowires. The electrochemical cycling test was performed on nanowires grown in supercritical fluids which were attached to a lithium ion battery current collector in slurry of a polymer binder and carbon black, in comparison with germanium nanowires grown in accordance with the embodiments to provide a nanowire composite in accordance with the embodiments.

FIG. 8a shows a representative schematic diagram of an apparatus that utilizes organic solvents and organic precursors when fabricating a nanowire composite in accordance with the embodiments. FIG. 8b shows a representative schematic diagram of an apparatus that uses silane and germane as precursors when fabricating a nanowire composite in accordance with the embodiments. The apparatus of FIG. 8a and FIG. 8b may be incorporated into the nanowire deposition portion of the reactors of FIG. 6a, FIG. 6b and FIG. 6c.

FIG. 9 shows a cross-sectional scanning electron micrograph of a germanium nanowire copper substrate composite in accordance with the embodiments. The height of the germanium nanowire material layer therein is 37 micrometers.

FIG. 10 shows scanning electron micrographs of a germanium nanowire copper substrate composite fabricated using different process configurations that can be utilized in accordance with the embodiments. Importantly, this figure provides proof of concept about the versatility of the proposed approach, the nanowires can be grown at supercritical fluid conditions (high pressure) and in vapor (ambient pressure) moreover the nanowires can be grown in batch mode or in continuous mode.

FIG. 11 shows a scanning electron micrograph with a superimposed electron dispersive x-ray spectroscopy map of the cross section of a germanium nanowire growth product grown from a 100 nm copper substrate thin layer. The copper substrate thin layer remains attached to the surface of the copper after the growth.

FIG. 12 shows an electron micrograph that illustrates the possibility of nanowire alignment within a nanowire composite in accordance with the embodiments. The nanowires within the nanowire composite are aligned via drying solvent at the surface.

FIG. 13 shows a transmission electron micrograph of isoprene passivation on germanium nanowires within a nanowire composite in accordance with the embodiments.

FIG. 14 shows an electron micrograph illustrating the effects of non-anhydrous and non-oxygen free solvents on group IV material layer precursors when fabricating a nanowire composite in accordance with the embodiments. FIG. 14a shows an electron micrograph of the product of a nanowire fabrication reaction in a process where the nanowire fabrication reaction occurred with an aged bottle of solvent that had been exposed to oxygen and water. FIG. 14b shows an electron micrograph of reaction products at the same conditions, with a new bottle of anhydrous solvent.

### DETAILED DESCRIPTION OF THE NON-LIMITING EMBODIMENTS

### 1. Broad Considerations

In a first instance, broad considerations within the context of the embodiments are directed towards an article comprising: (1) a flexible substrate that may be rolled into a coil, the flexible substrate comprising a group IV nanowire growth surface; and (2) a group IV nanowire material layer located upon the group IV nanowire growth surface. The flexible substrate may be at least in-part rolled into the coil. The group IV nanowire growth surface may comprise a metal surface. The metal surface may comprise a metal selected from the group including but not limited to aluminum, copper, iron, lead, nickel and titanium, and alloys of aluminum, copper, iron, lead, nickel and titanium. The metal surface may comprise copper. The flexible substrate may comprise a bulk metal substrate. The flexible substrate may comprise a laminated substrate. The laminated substrate may comprise a non-metallic base layer. The non-metallic base layer may comprise a material selected from the group including but not limited to an organic polymer material and a ceramic material. The group IV nanowire material layer may comprise a group IV material selected from the group including but not limited to silicon, germanium, silicon-germanium alloy, metal silicide and metal germanide materials, and combinations silicon, germanium, silicon-germanium alloy, metal silicide and metal germanide materials. The group IV nanowire material layer may comprise a germanium material. The group IV nanowire material layer may comprise a plurality of group IV nanowires aligned substantially perpendicular (i.e., within 15 degrees) to a plane of the metal substrate.

In a second instance, broad considerations within the context of the embodiments are directed towards a method for forming a nanostructure comprising: (1) positioning within a reactor chamber a substrate comprising a group IV nanowire growth surface; and (2) forming directly upon the group IV nanowire growth surface, while using a group IV precursor material, a group IV nanowire material layer. Within the method there is a relative motion of the group IV nanowire growth surface with respect to the reactor chamber when the group IV nanowire material layer is formed directly upon the group IV nanowire growth surface. The group IV nanowire growth surface may comprise a metal surface. The metal surface may comprise a metal selected from the group including but not limited to aluminum, copper, iron, lead, nickel and titanium, and alloys of aluminum copper, iron, lead, nickel and titanium. The substrate may comprise a flexible substrate that may be rolled into a coil. The substrate may comprise a bulk metal substrate. The substrate may comprise a laminated metal substrate. The group IV nanowire material layer may comprise a group IV material selected from the group including but not limited to silicon, germanium, silicon-germanium alloy, metal silicide and metal germanide materials, and combinations silicon, germanium, silicon-germanium alloy, metal silicide and metal germanide materials. The method may use a vapor phase method. The method may use a supercritical fluid method. The method may use an atmospheric pressure. The vapor phase method may use greater than atmospheric pressure. The method may further comprise: (1) solvent treating the group IV nanowire material layer; and (2) solvent drying the group IV nanowire material layer to provide a plurality of group IV nanowires aligned substantially perpendicular to a plane of the metal substrate.

In a third instance, broad considerations within the context of the embodiments are directed towards a method for forming a nanostructure comprising: (1) positioning within a reactor chamber a flexible substrate that may be rolled into a coil, the flexible substrate comprising a group IV nanowire growth surface; and (2) forming upon the group IV nanowire growth surface, while using a group IV nanowire precursor material, a group IV nanowire material layer. The flexible substrate may be at least in part rolled into the coil.

In a fourth instance, broad considerations within the context of the embodiments are directed towards an apparatus comprising: (1) a reactor chamber adapted to roll-to-roll processing; and (2) a group IV precursor source material supply connected to the reactor chamber.

### 2. General Considerations

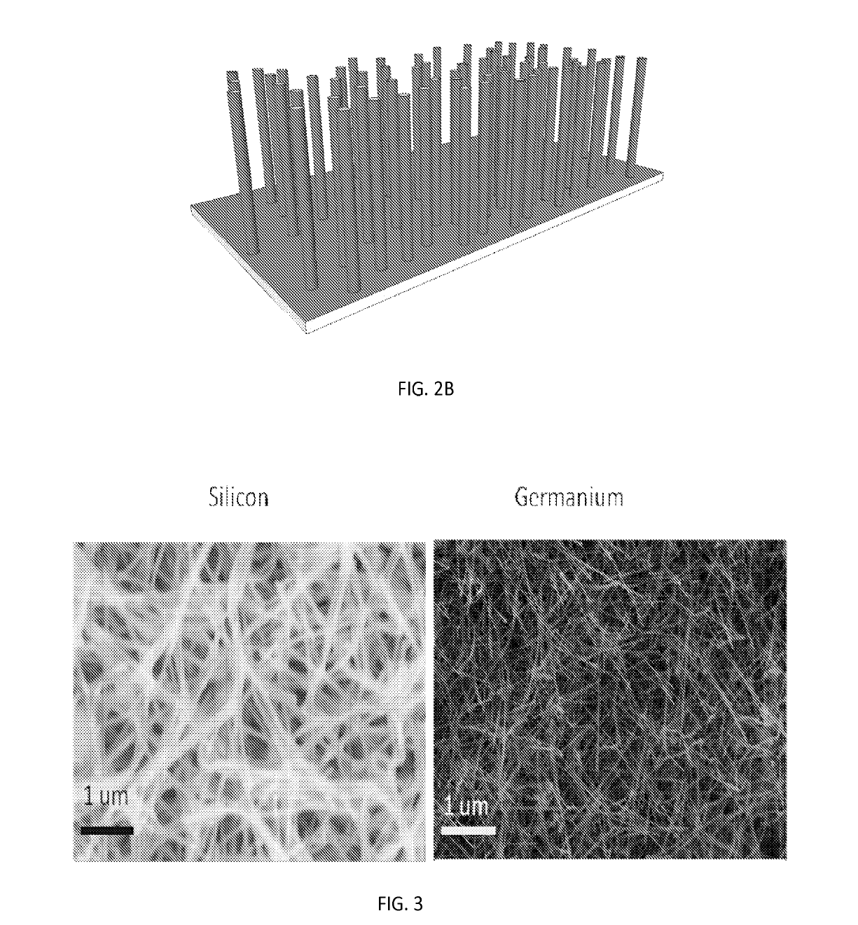

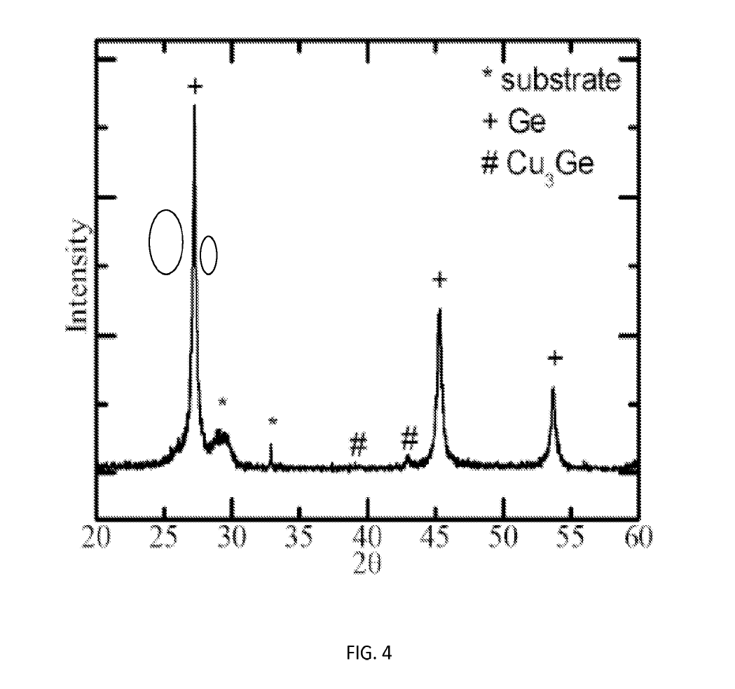

The embodiments provide a method for growing crystalline group IV nanowire upon a metal substrate, specifically but not limited to aluminum, copper, lead, nickel and titanium. The particular method in accordance with the embodiments uses a group IV metalloid precursor, which provides the growth of crystalline group IV nanowires in an atmospheric pressure or positive pressure. Exemplary crystalline nanowires are illustrated in FIG. 2a. A schematic depiction of a resulting nanowire composite is shown in FIG. 2b. FIG. 3 shows scanning electron micrographs and FIG. 4 shows an x-ray diffraction scan. A residence time, temperature, and precursor concentration can be varied in accordance with a method in accordance with the embodiments to produce nanowires within a nanowire composite with a low concentration of metal impurity. The method in accordance with the embodiments reduces the processing time and avoids expensive processing equipment used in competing methods, such as vacuum pumps, chambers, noble metal seeds, batch reactions, and hand extraction. These improvements lend the embodiments to semi-batch or continuous processing, including roll-to-roll processing. In a final form, the nanowire composite product of the embodiments may provide a highly promising material for the anode component in a lithium ion battery. The further attachment of different functional groups to the nanowire surfaces within a nanowire composite in accordance with the embodiments may allow for a variety of applications.

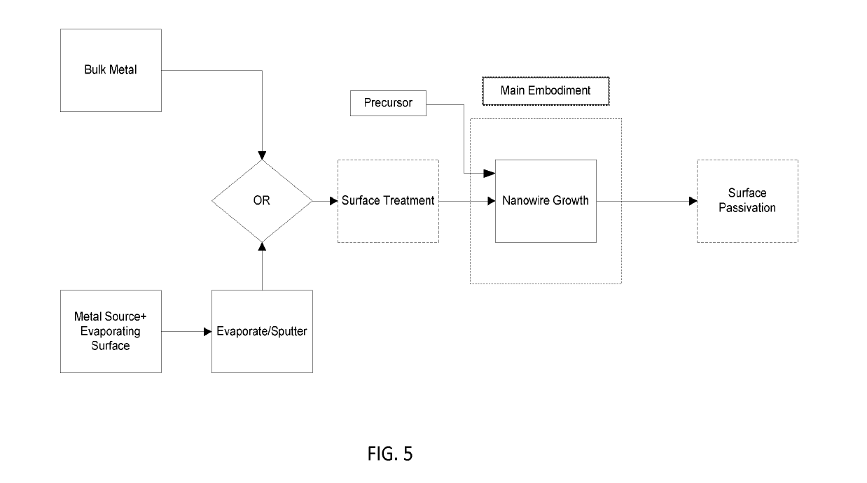

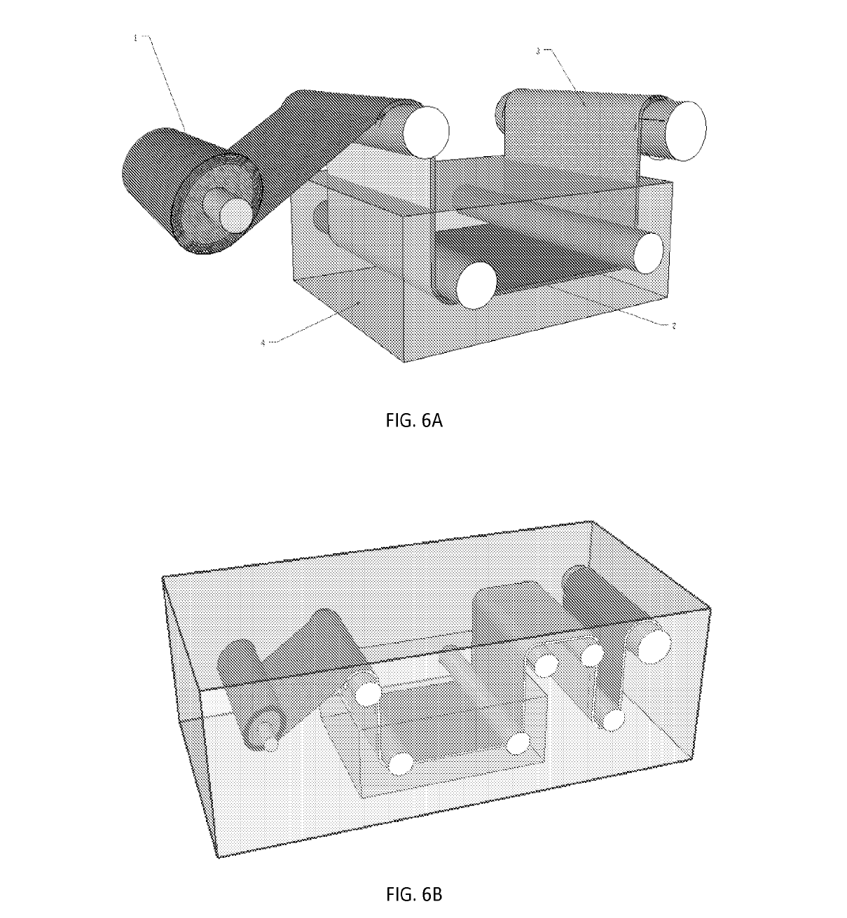

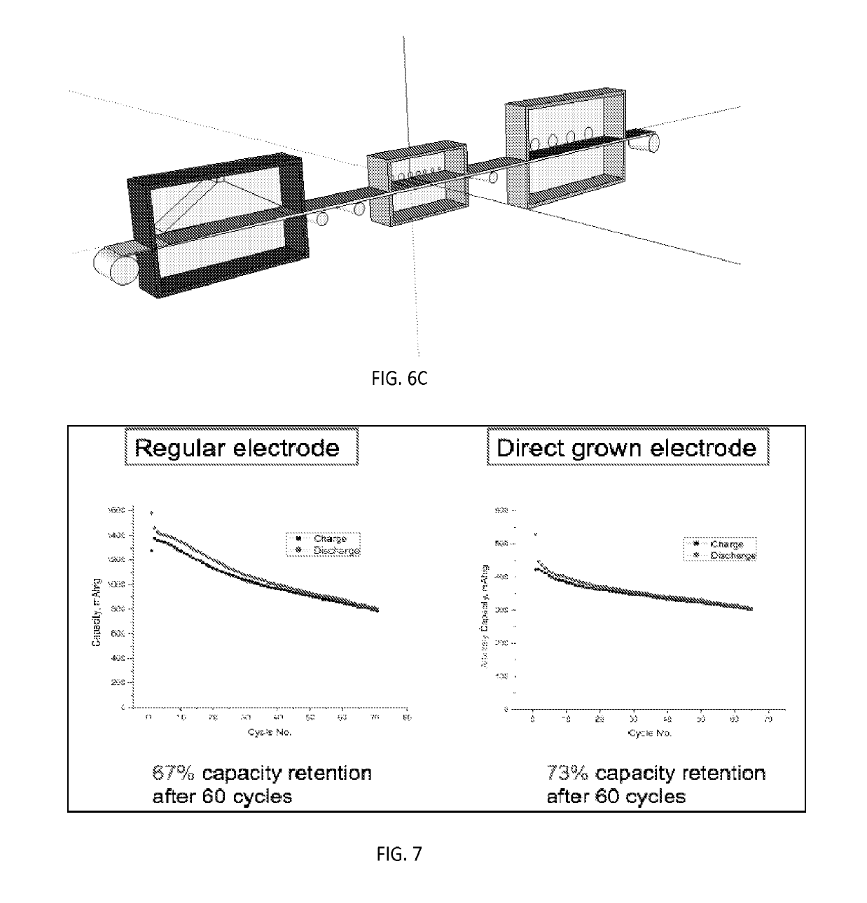

The embodiments also encompass an apparatus to fabricate a nanowire composite in accordance with the embodiments in a roll-to-roll process. This includes multiple apparatus embodiments to provide a versatile roll-to-roll process for producing nanowire composites for various applications. FIG. 5 illustrates various routes for producing nanowire composites including multiple sources of metal substrate growth material, an option for surface treatment, and an option for nanowire surface treatment with passivating layers or functional groups. FIG. 6a illustrates an exemplary reactor for fabrication of a nanowire composite from a vapor nanowire source material. FIG. 6b illustrates an exemplary reactor for fabrication of a nanowire composite from a supercritical fluid nanowire source material. FIG. 6c illustrates an exemplary assemblage of reactor chambers for nanowire composite fabrication that includes a surface treatment unit or metal evaporation unit followed by nanowire growth unit, followed by nanowire surface passivation, nanoparticle deposition, or metal contact evaporation unit.

A desirable application of the embodiments is the production of nanowire on copper substrate composite to provide lithium-ion battery anodes. Silicon and germanium are well known materials in lithium ion battery fabrication due to their high capacity for lithium-ions. In an initial application test as a battery anode, the nanowire composite grown in accordance with the embodiments perform better than the nanowire composite produced in a conventional supercritical fluid approach seeded by colloidal gold nanoparticles. FIG. 7 illustrates the results of electrochemical cycling tests comparing germanium nanowire composites produced using the SFLS method and the method in accordance with the embodiments. A lithium ion battery anode fabricated in accordance with the embodiments shows a 10% improvement over 60 cycles. These tests are performed on germanium nanowires with untreated surfaces; further effects of post processing can be executed to improve performance. Note that the experimental results that are illustrated in FIG. 7 do not account for the intrinsic weight and volume advantages when fabricating a nanowire composite in accordance with the embodiments that does not require a binder or a surfactant. The nanowires within a nanowire composite in accordance with the embodiments are epitaxially attached to the metal substrate surface. This growth method may indicate an inexpensive method to produce high quality lithium ion battery anodes.

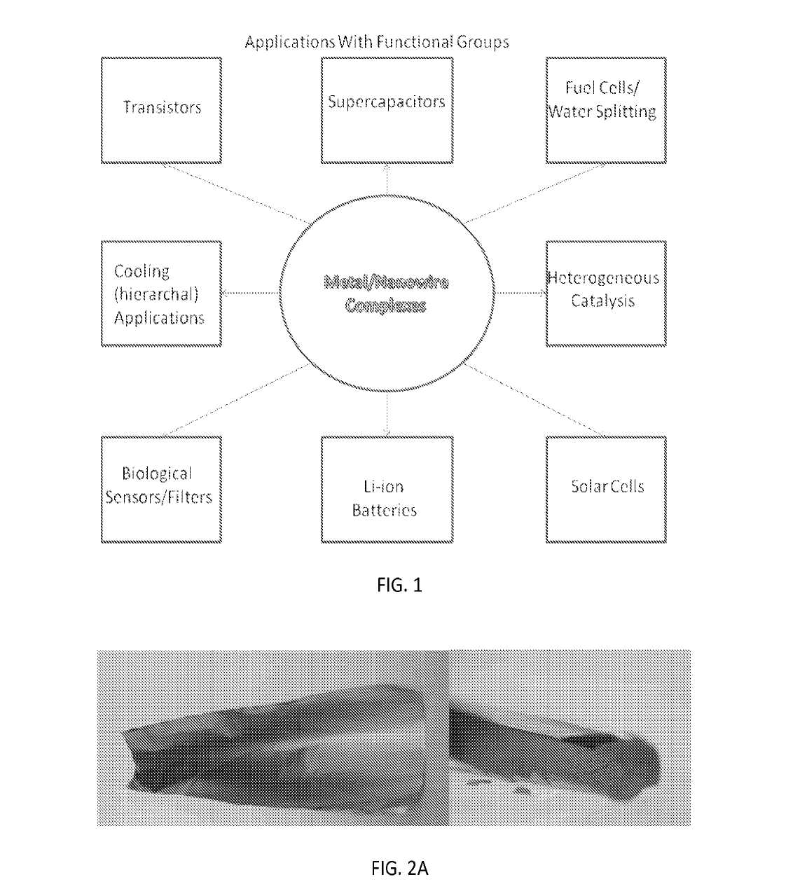

Additional applications that may be envisioned for a nanowire composite in accordance with the embodiments are shown in FIG. 1. Water splitting devices could be made utilizing metal nanoparticles attached to the nanowires to catalyze the water splitting reaction when an electric field is applied water is split producing hydrogen. An additional benefit of a nanowire composite in accordance with the embodiments is that the nanowire composite also increases the surface area to volume ratio of a metal catalyst. Such a surface area to volume ratio increase would increase the efficiency of hydrogen production, thereby increasing the viability of hydrogen fuel cells.

In the event that a reducing functional group is attached to a nanowire composite surface and opposite this configuration is another nanowire composite with an oxidizing group, a super capacitor is formed. This would increase the energy density of supercapacitors. With the ability to participate in the fields of supercapacitors, fuel cells, and batteries, this covers the entire portfolio of futuristic energy storage.

In the past, single nanowires have been shown to be effective as field effect transistors. Nanowires could be patterned by depositing masked metal vapor onto a surface and nanowires could be grown in select orientations to be used as transistors on a chip. This could make low cost field effect transistors for simple devices.

Solar cells are considered another simple application for the nanowire composites fabricated in accordance with the embodiments. In theory, solar cell benefit from increased hole-electron capture that is provided by the interdigitation of nanowires into the absorption layers. This would provide for an inexpensive charge collecting material for thin layer solar cells.

Literature claims that nanowires have the ability to capture select proteins, viruses, nucleic acids, and cells. The attachment or proximity of these agents change the electrical properties of the nanowire. This has been demonstrated with single nanowires to create a sensor. If many nanowires are used, concentrations could be derived through empirical correlations. In a similar concept a circulating layer of nanowires could act as a filter. First the nanowire layer could run through a bacterial-agent-containing bath, the agent would attach to the nanowires. Then the nanowire surface would run through a regenerating bath, where the agent is desorbed from the nanowire surface. Then the nanowire surface would circulate around to the bacterial-bath again. This could be run continuously. The nanowire would make an inexpensive biological filter for different applications.

The unique surface area aspects and thermal properties of nanowires, and the ability to grow on bulk metals, could provide cooling for specialized applications. The nanowires could be grown on, for example plates or pipes. Some examples of products that could be made, heat sinks, industrial air coolers, and microstructures. In addition to being well-suited for cooling, the high surface area to volume ratio makes nanowires an inexpensive alternative for cooling applications.

Advantages of the nanowires grown in accordance with the embodiments include: (1) the ability to prepare nanowires epitaxially attached to an electrical surface; (2) the ability to prepare nanowires with a low concentration of metal contaminants; (3) the ability to create a continuous roll-by-roll process for producing nanowires; (4) the ability produce commercially significant quantities of nanowires without using precious metals; (5) the ability to produce commercially significant quantities of nanowires without using noble metal seeds; (6) the ability to grow nanowires under vapor conditions; (7) the ability to reuse the catalyst surface; (8) the ability to attach functional groups; and (9) the ability to optimize growth based on reaction parameters. This nanowire composites in accordance with the embodiments may be used directly in many applications in its present state or in an easily attainable altered state.

### 3. Detailed Considerations

Methods are provided for growth of crystalline group IV nanowire composites utilizing a bulk metal catalyst and a group IV metalloid precursor in vapor phase. The process is a roll-to-roll process which a metal surface moves continuously through a reaction environment while continuously reacting with a stream of precursor to form the nanowire composite. The use of vapor flows allows for non-pressure-rated materials. The ability to modify growth height, nanowire diameter, and nanowire prevalence can be modified by the residence time, temperature, precursor profile, precursor concentration and surface patterning.

### A. Origin of Embodiments

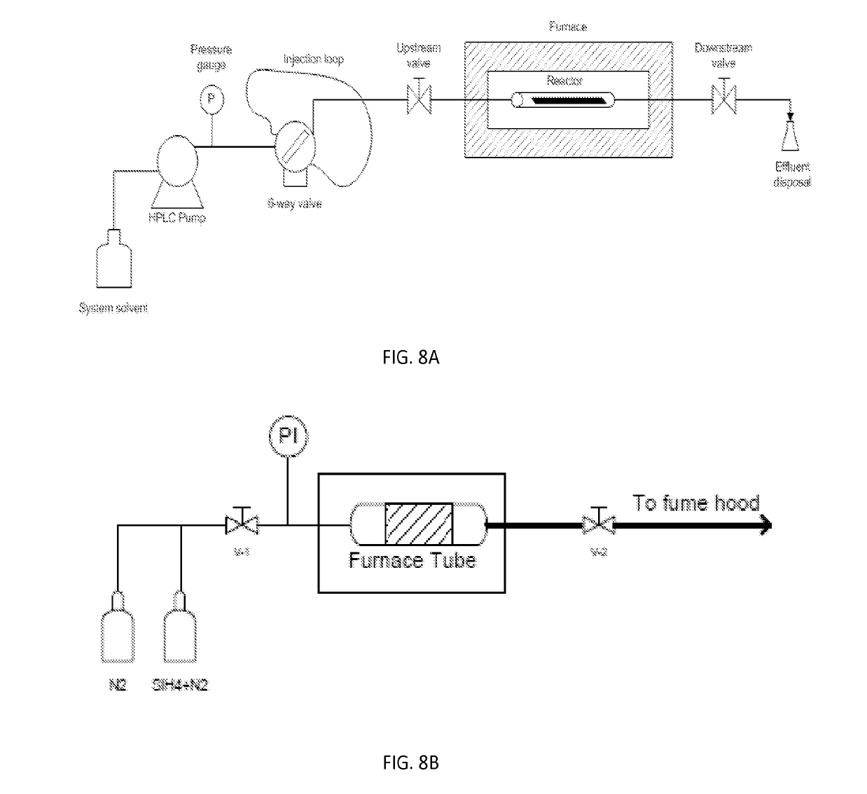

The embodiments develop a nanowire deposition technology, using a reactor in FIG. 8a, and provide practical application for the technology and an efficient method for nanowire composite production. The reactor as illustrated in FIG. 8a allows the characteristics of the nanowire growth when fabricating a nanowire composite to be varied by changing the reaction parameters. The synthesis produces high yields of crystalline nanowires with a low concentration of metal impurities that are epitaxially attached to a bulk metal substrate surface. The continuous and semi-batch processes utilized in this reactor produces nanowires more time efficiently and prepares nanowires to be used in a downstream process or transported. The nanowire alignment and straightening may occur using a specialized drying techniques.

### B. Growth Method

Currently, the nanowires are grown from an organic precursor, specifically diphenylgermane or phenylsilane; however these precursors degrade through a disproportionation reaction to silane or germane, which further degrades to silicon or germanium to produce nanowires on the surface of a metal substrate within a nanowire composite.

References to the growth method developed for the present invention: (1) “Seeded silicon nanowire growth catalyzed by commercially available bulk metals: broad selection of metal catalysts, superior field emission performance, and versatile nanowire/metal architectures”. Journal of Materials Chemistry. 2011; 21 (36):13793-13800; (2) Geaney, Hugh, Dickinson, Calum, Barrett, Christopher, and Ryan, Kevin. “High Density Germanium Nanowire Growth Directly from Copper Foil by Self-Induced Solid Seeding”. Chemistry of Materials. 2011; 23 (21): 4838-4843; (3) “Chemical Surface Passivation of Ge Nanowires” J. Am. Chem. Soc. 2004; 126 (47) 15466-15472; and (4) Tuan, H.-Y.; Korgel, B. A. Chem. Mater. 2008, 20, 1239.

### C. Definition of Nanowire

A nanowire is a one-dimensional growth of a crystalline material, typically composed of an electronically conductive or semiconducting material core, where the surface is often an amorphous material. Although the size characteristics are variable, these materials are physically characterized as one dimensional because in two dimensions (x,y) they are characterized between 5 nm-100 nm. The third dimension, the length, of the nanowires is greater than 5 um. Typically the aspect ratio is greater than 100 (length:diameter). Pseudonyms of nanowires are nanowiskers, nanofilaments, nanorods, and tenticular filaments.

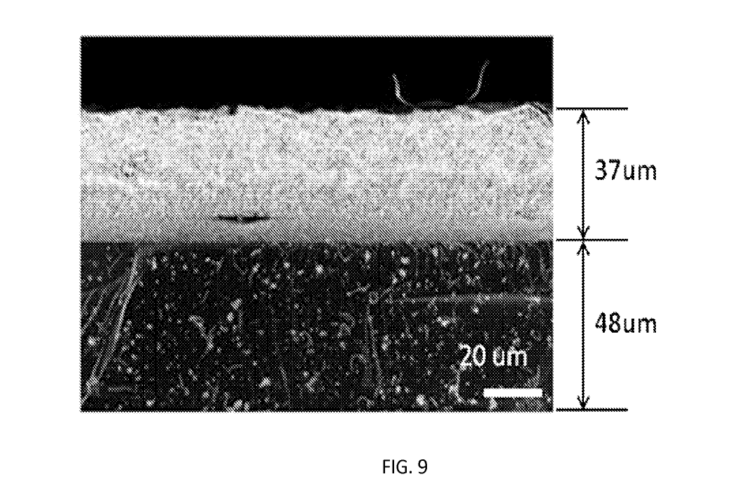

D. Nanowire Characterization Nanowires are usually characterized by their length and diameter. The population length and diameter of the nanowire can be predicted by measuring a statistically significant sample of the population. Although different lengths are desirable for different applications, typically a narrow distribution of the length and diameter is a desirable characteristic. The present invention features another important characteristic: nanowire layer height, see FIG. 9. This indicates the amount of nanowires that can be attached to a given surface area. The nanowire packing is dependent on the reaction parameters.

### E. Nanowire Applications

Nanowires have applications in electronic, light and electrochemical applications. These materials can be used as field effect transistors, photovoltaic solar cells, light-emitting diodes, batteries, biological-sensors, and cooling applications. This allows for many application spaces for nanowire composites. See FIG. 1.

### F. Cost of Production and Main Cost Factor

Currently the bulk production of nanowires is limited by the cost of the precursor and the quantities. In the working examples organometalloid precursors were tested. In these reactions metalloid hydrides are produced and react at the surface of a metal substrate. By extension metalloid hydrides, for example, silane and germane, may be used to produce nanowires in the process of the embodiments. Typically, research quantities of nanowires, based on research quantities of organometalloid precursors cost on the order of hundreds of dollars per gram. This is too expensive to be marketed for certain nanowire applications. However, pure metalloid hydride precursor bought in commercial quantities, for example silane, produces nanowires between on the order of $10/kg. A possible proof of concept reaction system is in FIG. 8b. This creates a cost competitive material for production.

### G. Reaction Properties

1. Metals that May be Used

Copper foil is extensively tested in the embodiments. The other metals tested in the literature are lead, silver, aluminum, gold, iron, nickel, and titanium. Gold and silver produced few nanowires, only particles. The rest of the metals are found to be viable growth surfaces. Alloys of these metals may also be considered as viable growth surfaces. Having a variety of growth materials increases the versatility of final applications.

### 2. Purity of Metal

The purity of the bulk metal material is not regarded as a high priority to this nanowire growth. Non-crystalline growths have been observed on bulk silicon, glass, and stainless steel. High purity metals are expensive. Lower purity metals are attractive due to their relative expense, and indicative of the versatility of the nanowire growth method.

### 3. Precursors

This disclosure provides evidence that group IV organometalloid precursors (or mixtures of precursors) can produce nanowires on the bulk metal surfaces. These precursors have been shown to thermally decompose into metalloid hydrides. The metalloid hydride is the common precursor behind most solution-based and vacuum environment syntheses because it is non-corrosive and has clean by-products. Therefore, by a reduction to practice, group IV metalloid hydride precursors maybe used for these synthesis. The attraction to the hydride precursors is based on precursor cost advantages. Examples of group IV metalloid precursors that may be used in this process include but are not limited to: chlorosilanes, akylsilanes, arylsilanes, fluorosilanes, chlorogermanes, akylgermanes, arylgermanes, fluorogermanes, chlorostannanes, akylstannanes, arylstannes, fluorostannes, chloroplumane, akylplumane, arylplumane, flouroplumane. Examples of group IV hydride precursors include but are not limited to silane, disilane, trisilane, germane, digermane, trigermane, stannane, distannane, tristannane, plumane, diplumane, and triplumane. Although many of these have by-products that may be difficult to process they represent many routes and possibilities to produce nanowires.

### 4. Reaction Temperatures, Pressures and Times for Continuous Reactions

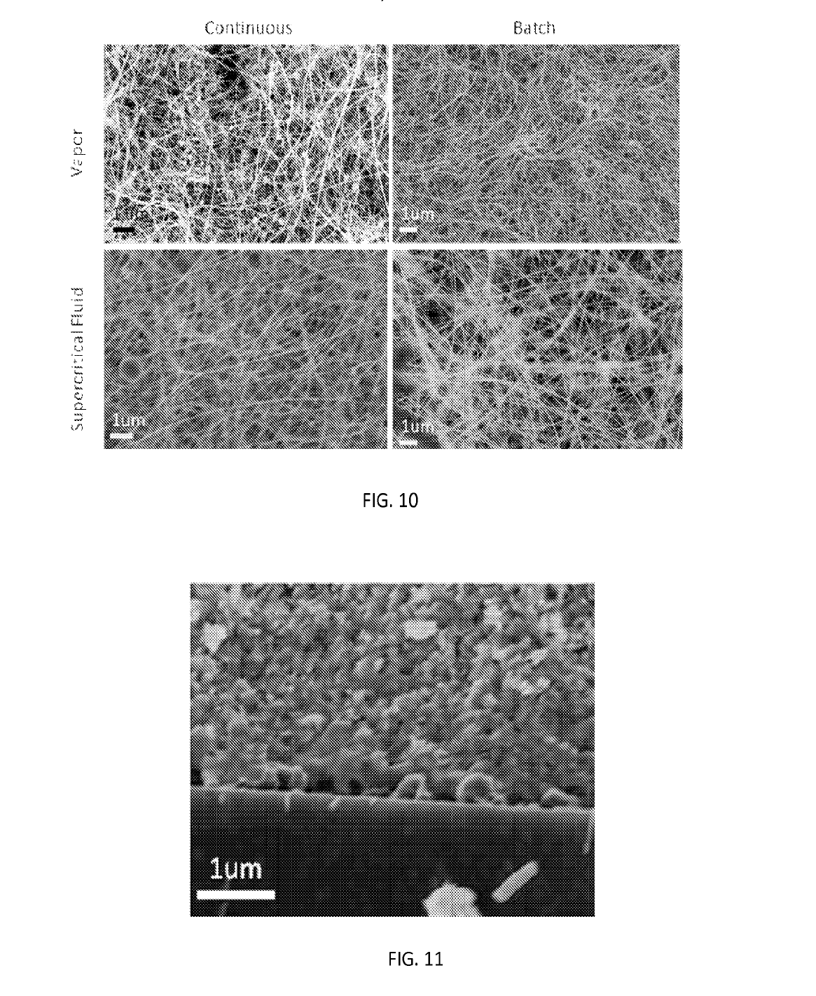

Reaction temperatures for copper bulk materials and germane occur at 380-450 C with 400 C being an optimal temperature. Reaction temperatures for copper bulk materials and silicon occur between 500 C and 600 C with 550 C being the optimal temperature. Optimal temperatures for other metals can be provided from the literature. In general the nanowire growth will occur on metals in the range between 300 C and 600 C. The pressure is not an important variable as the nanowires can be grown at atmospheric including pressures of a supercritical fluid. FIG. 10 shows nanowires produced in a supercritical fluid in a batch and continuous process. The residence time required to grow a nanowire film is under five minutes. Tests have showed that reaction times of 2.4 minutes are required for the beginnings of in a supercritical fluid. Longer residence times do not lower the quality of the nanowires. Supercritical fluids allow for continuous tunability of fluid properties and easier flow rate controls

The residence time required to grow a nanowire film is about 1.3 minutes. Reactions in vapor phase are attractive because they do require high pressures of a supercritical fluid, lowering the overall construction costs of the reactor. FIG. 10 shows germanium nanowires grown in batch and continuous vapor growth. Notably, these fast growth rates are compatible with continuous processing in a roll-to-roll format.

### 5. Precursor Concentration

Precursor concentration is a growth parameter of the process in the embodiments. The amount of precursor required for a reaction is based on the surface area of the exposed metal substrate surface. Although a range of precursor concentrations may be used typical concentrations are between 1.00*10̂-3 moles/cm̂2-6*10̂-6 moles/cm̂2-1.6*10̂-5 moles/cm̂2 produces a good quality synthesis. According to literature, reactions with excess organoprecursors will form nanowires with a organometalloid coating. At very high concentrations organomettalloid particles deposit at the surface of the nanowire layer. These can be washed away with a compatible solvent to the nanowire material. At very low concentrations a metalloid alloy is formed but little nanowire growth will occur. In the SFLS growth, making large concentration batches of nanowires produced poor quality nanowires. This bulk metal growth does not seem to have the same concentration limitations, thus indicating that larger batches of nanowires can be produced using this method.

### 6. Flow Rates (Beneficial to Supercritical Fluids)

Flow rates of the system are dependent on the precursor, precursor-solvent mixture, phases of the precursor, and the residence time. This should be calculated for the appropriate residence time for the reaction using an equation of state that fits the thermodynamic properties of the fluid in the reactor. At the temperatures used in this system, if liquid precursors are used, the flow rates are difficult to control in vapor conditions.

### 7. Surface Preparation

Another embodiment includes bulk metal surface preparation. This includes treatments to oxidize the metal surface layer, treatments to remove the native metal oxide layer, and no treatment. For example, to remove the native metal oxide physically, a sanding technique may be utilized. For example to remove the oxide chemically hydrochloric acid may be used. For example, to oxidize the surface of the catalyst chemically nitric acid may be used. This indicates the robustness of the reaction and the versatility for specified applications.

### 8. Thin-Film Preparation

In another embodiment of this reaction thin layers of metal (i.e., either blanket or patterned) may be evaporated or sputtered onto a surface. The surface materials that may be considered must be compatible with the high temperatures associated with metal evaporation. The metals that can be evaporated can include an adhesion layer for the substrate. The substrate could be made of copper, nickel, iron, titanium, aluminum, and lead (as well as alloys incorporating any or all of the foregoing metals). An example of a 100 nm copper layer growth is in FIG. 11 and FIG. 9.

### 9. Straightness and Alignment

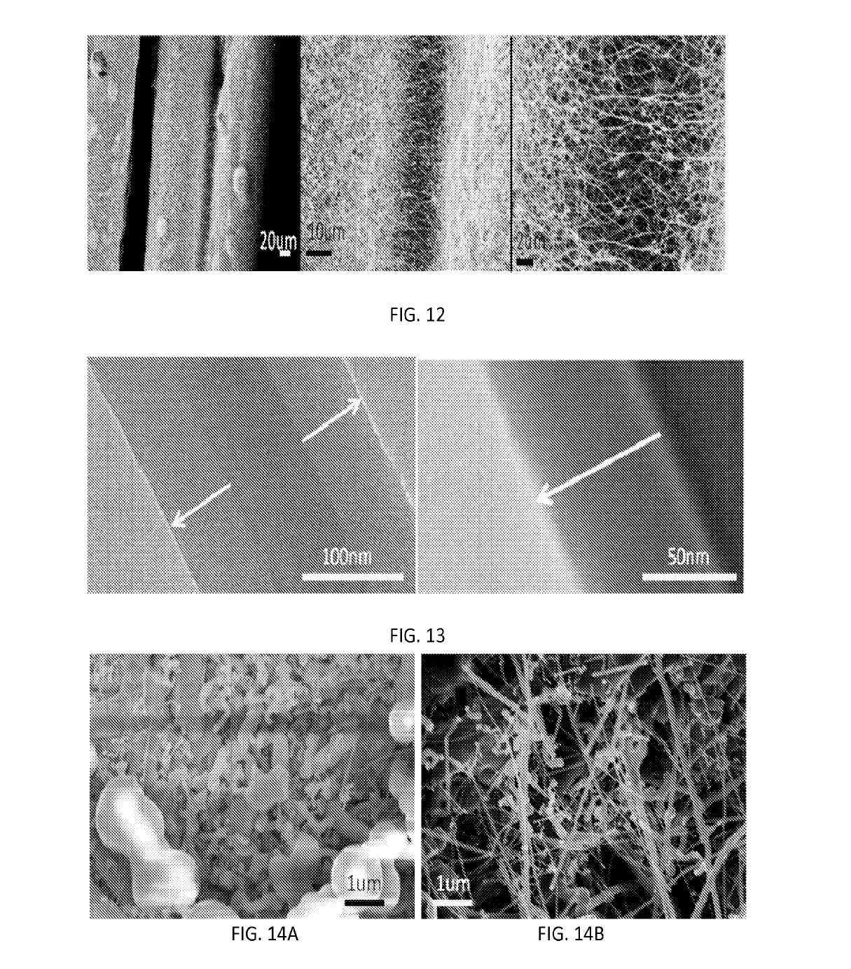

The nanowires produced in this process are typically curly and not aligned perpendicular to the metal surface. Some applications may find this quality of nanowires undesirable. Depending on drying parameters the nanowires have shown tendency to align substantially perpendicular (i.e., within 15 degrees of perpendicular) from the surface of the metal surface if an adjacent substrate surface is within the proximity of the drying nanowires. This phenomenon is dependent on the surface tension between the solvent and two nearly contacted surfaces. An example of this type of growth is shown in FIG. 12. Parallel alignment of nanowires with respect to a substrate may under certain circumstances be effected by a flooding flow of a fluid, such as a solvent. Aligned nanowires are considered an important aspect in nanowires production because it represents efficient space packing, important in volume sensitive applications, for example battery anode materials.

### H. Reactor Properties

### 1. Roll-to-Roll Process

This type of process is embraced when a foil or rollable sheet metal of alternate material is rolled through process beginning from a roll and ending on a roll. The reaction in the current embodiments represent an excellent opportunity use roll-to-roll processing because the reaction occurs on bulk metals, including foils. Recently, roll-to-roll processing has been considered important for its process speed and its versatility to be connected to downstream process or transported.

The reaction inside this process could use a serpentine path through the reactor to increase residence time and decrease reactor costs. This could include a reactor with multiple passes and baffles to direct precursor flow. This may increase the amount of time that the precursor is exposed to the copper foil.

### 2. Extraction

The material is removed from the reactor connected to the copper foil. A motorized roller system would move the copper foil through the reaction environment. In the past, with the supercritical-fluid liquid solid technique, the nanowires would have to be recovered from the inside of a dismantled reactor. This growth method allows for an automated, continuous removal process.

### 3. Removal

If the nanowires must be removed from the surface, the nanowires can be grown on the metal surface guided into a liquid medium that is placed in contact with an ultrasonic horn. The sonicating bath will cause the wires to fracture. The solution can be collected and dried to produce unattached nanowires. Literature mentions that the metal catalyst can be reused to produce nanowires. Applications where the metal contact is considered superfluous may find this valuable.

### 4. Vapor Phase Growth

The reactor can be run as a vapor. The concentration of the precursor has little effect on the nanowires. FIG. 6A shows a possible schematic of a continuous vapor phase reactor.

### 5. Supercritical Fluid Growth

The reactor has unique tunable properties as a supercritical fluid. The viscosities, residence times, and flow rates can be easily adjusted in this state of matter; however, supercritical fluids require higher pressures than vapor flow. Holding high pressure, sliding copper foil through an interface without removing the nanowire layer are conflicting goals. This is further complicated by the expense to pump/compress the precursors entering the system. FIG. 6b shows a schematic of a possible semi-batch supercritical fluid reactor.

### 6. Material of Construction (Outside Shell)

The outside construction material must be able to withstand the temperatures of this reaction. During vapor phase reactions conducted near atmospheric pressure, the material will be required to make a gas seal, but not hold pressure. In another embodiment of this reaction, where the reaction proceeds under supercritical fluid conditions, the outside material will have to withstand the temperatures and pressures of this reaction. For example, selected materials for this reactor are stainless steel or titanium. The high temperatures and pressures created in the reaction environment are high enough to cause some metals to fail. For the safety of the users correct materials should used.

### 7. Material of Construction (Reaction Exposure)

The inside construction of the nanowire reactor must be a material that does not participate in the nanowires reaction. For example, various glasses, silicon dioxide, certain stainless steel alloys will not participate in the nanowire reaction. The material should leach the reactants from the reaction. In addition to create a system that requires low maintenance these materials should not be compromised by nanowire growth. This would lower the overall operating cost of the reactor.

### 8. Nozzle Design

The nanowire reactor can be designed with a nozzle system to dictate the concentration of precursor to optimize the growth method having new precursor injected at different locations. This includes the capability to embrace counter-current flow or parallel flow within the reaction system. Experiments have not been performed to validate advantages to time-precursor profile effects; however, this indicates an additional versatility to the reactor system.

### 9. Surface Passivation

Nanowires exhibit chemically modifiable surfaces, which allows for select functional groups to be attached to the surface. Different functional groups can enhance performance or create viability different applications. This can include, for example, layers of sulfur, carbon, organics, halogens, hydride, oxides, proteins, and nanowires. Metals can also be evaporated, chemically attached, or chemically reacted to the surface. For example a carbon layer has been shown to alleviate some of the stress of lithiation. An example of isoprene passivation on a silicon nanowire surface can be seen in FIG. 13. The surface passivation methods for both silicon and germanium have been studied extensively. Functional groups open the embodiments to many application spaces.

### 10. Material Doping

Chemical doping can be performed on the nanowires for various applications. The dopant, for example can shift the energy level of the materials so that they can be tailored as a conductor in a layered solar cell. This can be performed in a post treatment process similar to the surface passivation. This further increases the versatility and application spaces of this invention.

### 11. Effects of Anhydrous and Anaerobic Environment

The precursors for these reactions are often very sensitive to contaminants from the outside environment. In an experiment performed with an old anhydrous bottle of solvent versus the same experiment performed with a new bottle of solvent one may find that it is imperative to keep the reaction environment anhydrous and anaerobic. FIG. 14 shows the effects of a non-anhydrous and non-anaerobic environment.

### I. Technical Challenges

Following the nanowire growth on 9 um copper foils, the metal surface often is characterized as brittle. This provides a technical challenge in handling the final product. In terms of roll-to-roll processing, this may not allow the metal nanowire complex to be malleable enough to be reprocessed into rolled form. However 40 gauge metal wire is not characterized as brittle; therefore this indicates that thicker pieces of foil are required for roll to roll processing or an alternative processing method. Roll to roll processing is highly regarded when considering commercial viability. There is a technical challenge in creating a seal between the reaction environment and the outside environment.

Due to their small size and high mobility nanowires and nanotubes have raised concerns about potential asbestos-like hazards. While the environmental and health risks associated with nanoscale materials are subject to ongoing investigation, socially responsible science and engineering must focus on development of fabrication methods that eliminate or mitigate potentially hazardous nanomaterial processing. Towards this goal, the method described in this invention directly integrates nanowires fabrication and device processing to minimize exposure. Moreover, the direct growth on metal surfaces significantly minimizes waste generation and undesired nanowire deposition, for example on the reactor walls.

### J. Working Examples

The following working examples are proofs of concept for this reactor that display multiple embodiments of the current invention.

### 1. Supercritical Fluid Germanium Batch

Single crystal germanium nanowires were synthesized using a self-seeded growth mechanism, utilizing bulk metal foils, in a batch mode. A portion of metal foil was washed in acetone, then washed in toluene, before it is inserted into the reactor. The nanowires were created by injecting a diphenylgermane into a reactor at a Ge:Cu Area Ratio of 8.55*10̂-5 moles/cm̂2. The reaction had a residence time of 20 minutes and took place at 400° C. and 34.5 MPa. A 50.6 cm̂2 (front and back) piece of Cu foil 9 um in thickness was placed into a 5 mL, 316SS, 5/16 in I.D., High Pressure Equipment (HiP) reactor. The 3.5 mL injection solution was prepared in a nitrogen-filled glove box and taken into a 5 mL syringe. This was transferred to a 3.4 mL injection loop attached to a six-way valve (Valco) which was pre-rinsed with high-pressure-liquid-chromatography (HPLC)-grade benzene (Sigma-Aldrich, SA). The furnace tube was preheated to 400° C. The temperature was maintained by a three-zone furnace tube (Lindberg)—all zones were set to the same temperature. The temperature uniformity was confirmed by an additional k-type thermocouple (Omega). The two-way valve (High Pressure Equipment, HiP) downstream from the reactor was operated to allow residual pressure to drop to atmospheric pressure; then, the valve was turned closed. The precursor solution was introduced through a six-way valve (Valco). Afterwards, the HPLC pump (Varian) supplied 10 mL/minute of anhydrous benzene (SA), for 1.2 minutes, into the system until the pressure reached 34.5 MPa. The pressure readings were taken from a gauge (Stewarts-USA). The solution reacted inside the 5 mL reactor (HiP) for 20 minutes. After the elapsed reaction time, the reactor was cooled to quench the reaction. The pressure fell naturally with the temperature. Once in the liquid regime, the remaining pressure was released by opening the two-way valve; the reactor effluent was collected in a collection flask. After the reactor cooled, the system was disassembled and the nanowires were recovered. The product of this reaction is displayed in FIG. 2B.

### 2. Supercritical Fluid Silicon Batch

Single crystal silicon nanowires were synthesized using a self-seeded mechanism, utilizing bulk metal foils, in a batch mode. A portion of metal foil was stored in a nitrogen filled glove box overnight. The reactor was stored in the nitrogen filled glovebox for 3 hours. The reactor was sealed and connected to the injection loop. The nanowires were created by injecting a phenylsilane into a reactor at a Si:Cu Area Ratio of 8.55*10̂-5 moles/cm̂2. The reaction had a residence time of 20 minutes and took place at 500° C. and 34.5 MPa.

A 50.6 cm̂2 (front and back) piece of Cu foil 9 um in thickness was placed into a 5 mL, 316SS, 5/16 in I.D., High Pressure Equipment (HiP) reactor. The 3.5 mL injection solution was prepared in a nitrogen-filled glove box and taken into a 5 mL syringe. This was transferred to a 3.4 mL injection loop attached to a six-way valve (Valco) which was pre-rinsed with the anhydrous solvent attached to the pump (Sigma-Aldrich, SA). The furnace tube was preheated to 500° C. The temperature was maintained by a three-zone furnace tube (Lindberg)—all zones were set to the same temperature. The temperature uniformity was confirmed by an additional k-type thermocouple (Omega). The two-way valve (High Pressure Equipment, HiP) downstream from the reactor was operated to allow residual pressure to drop to atmospheric pressure; then, the valve was turned closed. The precursor solution was introduced through a six-way valve (Valco). Afterwards, the HPLC pump (Varian) supplied 10 mL/minute of anhydrous benzene (SA), for 1.2 minutes, into the system until the pressure reached 34.5 MPa. The pressure readings were taken from a gauge (Stewarts-USA). The solution reacted inside the 5 mL reactor (HiP) for 20 minutes. After the elapsed reaction time, the reactor was cooled to quench the reaction. The pressure fell naturally with the temperature. Once in the liquid regime, the remaining pressure was released by opening the two-way valve; the reactor effluent was collected in a collection flask. After the reactor cooled, the system was disassembled and the nanowires were recovered. The product of this reaction is displayed in FIG. 14b.

### 3. Continuous Supercritical Fluid Reaction

Single crystal germanium nanowires were synthesized using a self-seeded mechanism, utilizing bulk metal foils, in a continuous mode. A portion of metal foil was stored in a nitrogen filled glove box overnight. The reactor was stored in the nitrogen filled glovebox for 3 hours. The reactor was sealed and connected to the injection loop. The nanowires were created by injecting a diphenylgermane into a reactor at a Ge:Cu Area Ratio of 1.66*10̂-4 moles/cm̂2. The reaction had a residence time of 20 minutes and took place at 400° C. and 13.7 MPa.

A 50.6 cm̂2 (front and back) piece of Cu foil 9 um in thickness was placed into a 5 mL, 316SS, 5/16 in I.D., High Pressure Equipment (HiP) reactor. The 3.5 mL injection solution was prepared in a nitrogen-filled glove box and taken into a 5 mL syringe. This was transferred to a 3.4 mL injection loop attached to a six-way valve (Valco) which was pre-rinsed with the anhydrous solvent attached to the pump (SA). The furnace tube was preheated to 400° C. The temperature was maintained by a three-zone furnace tube (Lindberg)—all zones were set to the same temperature. The temperature uniformity was confirmed by an additional k-type thermocouple (Omega). Afterwards, the HPLC pump (Varian) supplied 10 mL/minute of anhydrous benzene (SA), until 13.7 MPa was reached. Then, the precursor solution was introduced through a six-way valve (Valco). The pump supplied 0.3 mL/min for 17.4 min. The downstream two-way valve was operated to maintain the pressure. The pressure readings were taken from a gauge (Stewarts-USA). The solution reacted inside the 5 mL reactor (HiP) for 20 minutes. After the elapsed reaction time, the reactor was cooled to quench the reaction. The pressure fell naturally with the temperature. Once in the liquid regime, the remaining pressure was released by opening the two-way valve; the reactor effluent was collected in a collection flask. After the reactor cooled, the system was disassembled and the nanowires were recovered. The product of this reaction is displayed in FIG. 10.

D. Batch with 40 Gauge Wire Wrapped

Single crystal germanium nanowires were synthesized using a self-seeded mechanism, utilizing bulk metal foils, in a batch mode. A piece of 40 gauge Cu wire was wound 20 times around a stainless steel tube holder and placed into a into a 5 mL, 316SS, 5/16 in I.D., High Pressure Equipment (HiP) reactor. The reactor was sealed and connected to the injection loop. The nanowires were created by injecting diphenylgermane into a reactor at a Ge:Cu Area Ratio of 5.6*10̂-5 moles/cm̂2. The reaction had a residence time of 20 minutes and took place at 400 C and 31.0 MPa. The 3.5 mL injection solution was prepared in a nitrogen-filled glove box and taken into a 5 mL syringe. This was transferred to a 3.4 mL injection loop attached to a six-way valve (Valco) which was pre-rinsed with the anhydrous solvent attached to the pump (Sigma-Aldrich, SA). The furnace tube was preheated to 400 C. The temperature was maintained by a three-zone furnace tube (Lindberg)—all zones were set to the same temperature. The temperature uniformity was confirmed by an additional k-type thermocouple (Omega). The two-way valve (High Pressure Equipment, HiP) downstream from the reactor was operated to allow residual pressure to drop to atmospheric pressure; then, the valve was turned closed. The precursor solution was introduced through a six-way valve (Valco). Afterwards, the HPLC pump (Varian) supplied 10 mL/minute of anhydrous benzene (SA), for 1.1 minutes, into the system until the pressure reached 31.0 MPa. The pressure readings were taken from a gauge (Stewarts-USA). The solution reacted inside the 5 mL reactor (HiP) for 20 minutes. After the elapsed reaction time, the reactor was cooled to quench the reaction. The pressure fell naturally with the temperature. Once in the liquid regime, the remaining pressure was released by opening the two-way valve; the reactor effluent was collected in a collection flask. After the reactor cooled, the system was disassembled and the nanowires were recovered. The product of this reaction is displayed in FIG. 13.

5. Silicon Batch with 100 nm Evaporated Cu Thin Film

Single crystal silicon nanowires were synthesized using a self-seeded mechanism, utilizing bulk metal foils, in a batch mode. A silicon dioxide wafer was inserted into an evaporation chamber inside a nitrogen filled glove box. The evaporation chamber was exposed to chromium vapor which created a 5 nm adhesion layer. Afterwards, the evaporation chamber was exposed to copper vapor until a 100 nm film had formed. A 5 mL, 316SS, 5/16 in I.D., High Pressure Equipment (HiP) reactor was stored in the nitrogen filled glovebox for 1 hour. A 6.5 cm×0.44 mm piece was cut from the wafer and inserted into the reactor. The reactor was sealed, removed from the glovebox, and connected to the injection loop. The nanowires were created by injecting diphenylgermane into a reactor at a Si:Cu Area Ratio of 1.66*10̂-4 moles/cm̂2. The reaction had a residence time of 20 minutes and took place at 550° C. and 34.5 MPa. The 3.5 mL injection solution was prepared in a nitrogen-filled glove box and taken into a 5 mL syringe. This was transferred to a 3.4 mL injection loop attached to a six-way valve (Valco) which was pre-rinsed with the anhydrous solvent attached to the pump (Sigma-Aldrich, SA). The furnace tube was preheated to 550 C. The temperature was maintained by a three-zone furnace tube (Lindberg)—all zones were set to the same temperature. The temperature uniformity was confirmed by an additional k-type thermocouple (Omega). The two-way valve (High Pressure Equipment, HiP) downstream from the reactor was operated to allow residual pressure to drop to atmospheric pressure; then, the valve was turned closed. The precursor solution was introduced through a six-way valve (Valco). Afterwards, the HPLC pump (Varian) supplied 10 mL/minute of anhydrous benzene (SA), for 1.2 minutes, into the system until the pressure reached 34.5 MPa. The pressure readings were taken from a gauge (Stewarts-USA). The solution reacted inside the 5 mL reactor (HiP) for 20 minutes. After the elapsed reaction time, the reactor was cooled to quench the reaction. The pressure fell naturally with the temperature. Once in the liquid regime, the remaining pressure was released by opening the two-way valve; the reactor effluent was collected in a collection flask. After the reactor cooled, the system was disassembled and the nanowires were recovered. The product of this reaction is displayed in FIG. 3.

### 6. Vapor Phase Growth Continuous Process

Single crystal germanium nanowires were synthesized using a self-seeded mechanism, utilizing bulk metal foils, in a continuous mode. A piece of 20 gauge Cu wire was placed into a into a 5 mL, 316SS, 5/16 in I.D., High Pressure Equipment (HiP) reactor. The reactor was sealed and connected to the injection loop. The nanowires were created by injecting diphenylgermane into a reactor at a Ge:Cu Area Ratio of 1.66*10̂-4 moles/cm̂2. The reaction had a residence time of 2.6 minutes and took place at 400° C. and 0.1 MPa. The 0.22 mL precursor injection was prepared in a nitrogen-filled glove box and taken into a 5 mL syringe. This was transferred to a 0.2 mL injection loop attached to a six-way valve (Valco) which was pre-rinsed with the anhydrous solvent attached to the pump (Sigma-Aldrich, SA). The furnace tube was preheated to 400° C. The temperature was maintained by a three-zone furnace tube (Lindberg)—all zones were set to the same temperature. The temperature uniformity was confirmed by an additional k-type thermocouple (Omega). The two-way valve (High Pressure Equipment, HiP) downstream from the reactor was operated to allow residual pressure to drop to atmospheric pressure. The pressure readings were taken from a gauge (Stewarts-USA). The precursor solution was introduced through a six-way valve (Valco). Afterwards, the HPLC pump (Varian) supplied 0.01 mL/minute of anhydrous benzene (SA), for 23 minutes. After the elapsed reaction time, the reactor was cooled to quench the reaction. After the reactor cooled, the system was disassembled and the nanowires were recovered. The product of this reaction is displayed in FIG. 10.

### 7. Vapor Phase Growth Batch Process

Single crystal germanium nanowires were synthesized using a self-seeded mechanism, utilizing bulk metal foils, in a batch mode. A piece of 20 gauge Cu wire was placed into a into a 5 mL, 316SS, 5/16 in I.D., High Pressure Equipment (HiP) reactor. The reactor was sealed and connected to the injection loop. The nanowires were created by injecting diphenylgermane into a reactor at a Ge:Cu Area Ratio of 1.66*10̂-4 moles/cm̂2. The reaction had a residence time of 15 minutes and took place at 400° C. and 0.7 MPa. The 0.22 mL precursor injection was prepared in a nitrogen-filled glove box and taken into a 5 mL syringe. This was transferred to a 0.2 mL injection loop attached to a six-way valve (Valco) which was pre-rinsed with the anhydrous solvent attached to the pump (Sigma-Aldrich, SA). The furnace tube was preheated to 400° C. The temperature was maintained by a three-zone furnace tube (Lindberg)—all zones were set to the same temperature. The temperature uniformity was confirmed by an additional k-type thermocouple (Omega). The two-way valve (High Pressure Equipment, HiP) downstream from the reactor was operated to allow residual pressure to drop to atmospheric pressure. The pressure readings were taken from a gauge (Stewarts-USA). The precursor solution was introduced through a six-way valve (Valco). Afterwards, the HPLC pump (Varian) supplied 0.6 mL/minute of anhydrous benzene (SA), for 1 minute to move the precursor into the reactor. Then the two-way valve was turned closed. The pump remained on until the pressure reached 0.7 MPa was reached. After 15 minutes passed, the reactor was cooled to quench the reaction. After the reactor cooled, the system was disassembled and the nanowires were recovered. The product of this reaction is displayed in FIG. 10.

All references, including publications, patent applications, and patents cited herein are hereby incorporated by reference in their entireties to the same extent as if each reference was individually and specifically indicated to be incorporated by reference and were set forth in its entirety herein.

The use of the terms “a” and “an” and “the” and similar referents in the context of describing the invention (especially in the context of the following claims) is to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted. The term “connected” is to be construed as partly or wholly contained within, attached to, or joined together, even if there is something intervening.

The recitation of ranges of values herein are merely intended to serve as a shorthand method of referring individually to each separate value falling within the range, unless otherwise indicated herein, and each separate value is incorporated into the specification as if it was individually recited herein.

All methods described herein can be performed in any suitable order unless otherwise indicated herein or otherwise clearly contradicted by context. The use of any and all examples, or exemplary language (e.g., “such as”) provided herein, is intended merely to better illuminate embodiments of the invention and does not impose a limitation on the scope of the invention unless otherwise claimed.

No language in the specification should be construed as indicating any non-claimed element as essential to the practice of the invention.

It will be apparent to those skilled in the art that various modifications and variations can be made to the present invention without departing from the spirit and scope of the invention. There is no intention to limit the invention to the specific form or forms disclosed, but on the contrary, the intention is to cover all modifications, alternative constructions, and equivalents falling within the spirit and scope of the invention, as defined in the appended claims. Thus, it is intended that the present invention cover the modifications and variations of this invention provided they come within the scope of the appended claims and their equivalents.

What is claimed is:

1. An article comprising:
a flexible substrate that may be rolled into a coil, the flexible substrate comprising a group IV nanowire growth surface; and
a group IV nanowire material layer located upon the group IV nanowire growth surface.

2. The article of claim 1 wherein the flexible substrate is at least in-part rolled into the coil.

3. The article of claim 1 wherein the group IV nanowire growth surface comprises a metal surface.

4. The article of claim 3 wherein the metal surface comprises a metal selected from the group consisting of aluminum, copper, iron, lead, nickel and titanium, and alloys of aluminum, copper, iron, lead, nickel and titanium.

5. The article of claim 3 wherein the metal surface comprises copper.

6. The article of claim 1 wherein the flexible substrate comprises a bulk metal substrate.

7. The article of claim 1 wherein the flexible substrate comprises a laminated substrate.

8. The article of claim 7 wherein the laminated substrate comprises a non-metallic base layer.

9. The article of claim 8 wherein the non-metallic base layer comprises a material selected from the group consisting of an organic polymer material and a ceramic material.

10. The article of claim 1 wherein the group IV nanowire material layer comprises a group IV material selected from the group consisting of silicon, germanium, silicon-germanium alloy, metal silicide and metal germanide materials, and combinations silicon, germanium, silicon-germanium alloy, metal silicide and metal germanide materials.

11. The article of claim 1 wherein the group IV nanowire material layer comprises a germanium material.

12. The article of claim 1 wherein the group IV nanowire material layer comprises a plurality of group IV nanowires aligned substantially perpendicular to a plane of the flexible substrate.

13. A method for forming a nanostructure comprising:
positioning within a reactor chamber a substrate comprising a group IV nanowire growth surface; and
forming directly upon the group IV nanowire growth surface, while using a group IV precursor material, a group IV nanowire material layer.

14. The method of claim 13 wherein there is a relative motion of the group IV nanowire growth surface with respect to the reactor chamber when the group IV nanowire material layer is formed directly upon the group IV nanowire growth surface.

15. The method of claim 13 wherein the group IV nanowire growth surface comprises a metal surface.

16. The method of claim 15 wherein the metal surface comprises a metal selected from the group consisting of aluminum, copper, iron, lead, nickel and titanium, and alloys of aluminum, copper, iron, lead, nickel and titanium.

17. The method of claim 13 wherein the substrate comprises a flexible substrate that may be rolled into a coil.

18. The method of claim 13 wherein the substrate comprises a bulk metal substrate.

19. The method of claim 13 wherein the substrate comprises a laminated metal substrate.

20. The method of claim 13 wherein the group IV nanowire material layer comprises a group IV material selected from the group consisting of silicon, germanium, silicon/germanium alloy, metal silicide and metal germanide materials, and combinations silicon, germanium, silicon-germanium alloy, metal silicide and metal germanide materials.

21. The method of claim 13 wherein the forming uses a vapor phase method.

22. The method of claim 13 wherein the forming uses a supercritical fluid method.

23. The method of claim 21 wherein the vapor phase method uses an atmospheric pressure.

24. The method of claim 21 wherein the vapor phase method uses greater than atmospheric pressure.

25. The method of claim 13 further comprising:
solvent treating the group IV nanowire material layer; and
solvent drying the group IV nanowire material layer in the presence of an additional substrate to provide a plurality of group IV nanowires aligned substantially perpendicular to a plane of the substrate.

26. A method for forming a nanostructure comprising:
positioning within a reactor chamber a flexible substrate that may be rolled into a coil, the flexible substrate comprising a group IV nanowire growth surface; and
forming upon the group IV nanowire growth surface, while using a group IV nanowire precursor material, a group IV nanowire material layer.

27. The method of claim 26 wherein the flexible substrate is at least in part rolled into the coil.

28. An apparatus comprising:
a reactor chamber adapted to roll-to-roll processing; and
a group IV precursor source material supply connected to the reactor chamber.
